(19) United States
(12) Patent Application Publication
(10) Pub. No.: US 2014/0131670 A1
(43) Pub. Date: May 15, 2014

(54) ORGANIC COMPOUND AND ORGANIC ELECTROLUMINESCENT DEVICE EMPLOYING THE SAME

(71) Applicant: INDUSTRIAL TECHNOLOGY RESEARCH INSTITUTE, (US)

(72) Inventors: Jin-Sheng LIN, Taipei City (TW); Chun-Neng KU, Tainan City (TW); Meng-Hao CHANG, New Taipei City (TW); Jia-Lun LIOU, Hsinchu County (TW)

(73) Assignee: INDUSTRIAL TECHNOLOGY RESEARCH INSTITUTE, Hsinchu (TW)

(21) Appl. No.: 13/889,716

(22) Filed: May 8, 2013

(30) Foreign Application Priority Data
Nov. 13, 2012 (TW) 101142145

(51) Int. Cl. H01L 51/00; H01L 51/50

(52) U.S. Cl. CPC H01L 51/006; H01L 51/0061; H01L 51/5012
USPC 257/40; 548/440

(57) ABSTRACT

The disclosure provides an organic compound and an organic electroluminescence device employing the same. According to an embodiment of the disclosure, the organic compound has a chemical structure as represented as below:

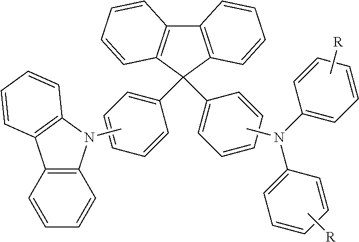

wherein, R are independent and can be hydrogen, halogen, cyano, C₁₋₈ alkyl, C₁₋₈ alkoxy, C₅₋₁₀ aryl, or C₂₋₈ heteroaryl.

### CROSS REFERENCE TO RELATED APPLICATIONS

This application is based upon and claims the benefit of priority from the prior Taiwan Patent Application No. 101142145, filed on Nov. 13, 2012, the entire contents of which are incorporated herein by reference.

### TECHNICAL FIELD

The disclosure relates to an organic compound and organic electroluminescence device employing the same.

### BACKGROUND

An organic light-emitting diode (OLED) is a light-emitting diode employing an organic electroluminescent layer as an active layer. OLED display devices have high luminescent efficiency and long operating lifespans. In comparison with liquid crystal displays, due to the characteristic of spontaneous emission, a device employing an organic light-emitting diode is free of a back-light source.

Generally, an organic electroluminescent device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Recently, a highly efficient phosphorescent material is used in order to increase the emissive efficiency of the OLED. Except to the host material, the electron and hole transport materials are also being paid attention.

Particularly, a suitable hole transport material has a larger energy gap of a singlet spin state (S1), and preferably has a shorter conjugated system and high thermal stability.

Therefore, it is necessary to develop novel hole transport materials to be used in replace of TAPC to solve the problems.

### BRIEF SUMMARY

An exemplary embodiment of an organic compound has a Formula (I), of:

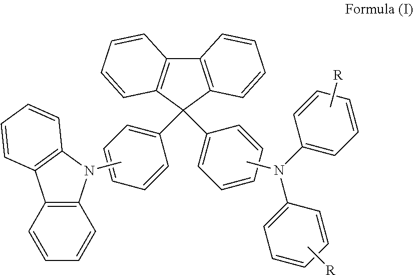

wherein, R are independent and can be hydrogen, halogen, cyano, C₁₋₈ alkyl, C₁₋₈ alkoxy, C₅₋₁₀ aryl, or C₂₋₈ heteroaryl.

According to another embodiment of the disclosure, the disclosure provides an organic electroluminescence device. The device includes a pair of electrodes and an electroluminescent element, disposed between the pair of electrodes, wherein the electroluminescent element includes the aforementioned organic compound.

Further, according to other embodiments of the disclosure, the electroluminescent element of the organic electroluminescence device can include a hole transport layer, wherein the hole transport layer includes the aforementioned organic compound.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross section of an organic electroluminescent device disclosed by an embodiment of the disclosure.

### DETAILED DESCRIPTION

The following description is of the best-contemplated mode of carrying out the disclosure. This description is made for the purpose of illustrating the general principles of the invention and should not be taken in a limiting sense. The scope of the invention is best determined by reference to the appended claims.

Organic Compound

The disclosure discloses an organic compound having the Formula (I), of:

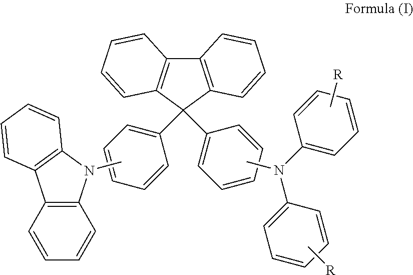

wherein, R are independent and can be hydrogen, halogen, cyano, C₁₋₈ alkyl, C₁₋₈ alkoxy, C₅₋₁₀ aryl, or C₂₋₈ heteroaryl.

According to some embodiments of the disclosure, R are independent and a hydrogen group, fluorine group, chlorine group, bromine group, cyano group, methyl group, ethyl group, propyl group, isopropyl group, butyl group, tert-butyl group, pentyl group, hexyl group, methoxy group, ethoxy group, propoxy group, isopropoxy group, butoxy group, isobutoxy group, pentyloxy group, hexyloxy group, phenyl group, biphenyl group, pyridyl group, furyl group, carbazole group, naphthyl group, anthryl group, phenanthrenyl group, imidazolyl group, pyrimidinyl group, quinolinyl group, indolyl group, or thiazolyl group.

In the structure of Formula (I), the carbazole group can be located at any one of the five substitutable positions of the benzene ring, the diphenylamine group can be located at any one of the five substitutable positions of the benzene ring, and R can be located at any one of the five substitutable positions of the benzene ring.

According to other embodiments of the disclosure, the organic compounds of Formula (I) of the disclosure can have the fluorine group bound to the benzene at the meta-position or para-position relative to the carbazole group. Therefore, the organic compounds of the disclosure can have Formula (II) or Formula (III), of:

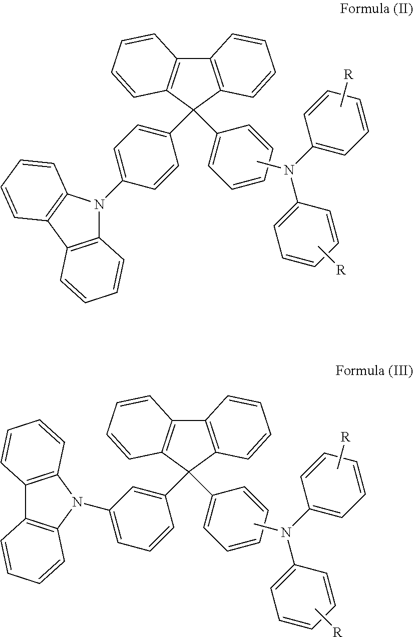

wherein, R are independent and can be hydrogen, halogen, cyano, C₁₋₈ alkyl, C₁₋₈ alkoxy, C₅₋₁₀ aryl, or C₂₋₈ heteroaryl.

Further, according to an embodiment of the disclosure, the organic compounds of Formula (I) of the disclosure can have the fluorine group bound to the benzene at the meta-position or para-position relative to the diphenylamine group. Therefore, the organic compounds of the disclosure can have Formula (IV), of:

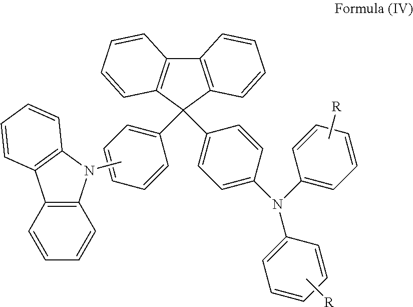

wherein, R are independent and can be hydrogen, halogen, cyano, C₁₋₈ alkyl, C₁₋₈ alkoxy, C₅₋₁₀ aryl, or C₂₋₈ heteroaryl.

The organic compounds according to Formula (I) of the invention include the following compounds shown in Table 1. In addition, the contractions thereof are also named and shown in Table 1.

TABLE 1

| Example | Structure | Contraction |
|---|---|---|
| 1 | 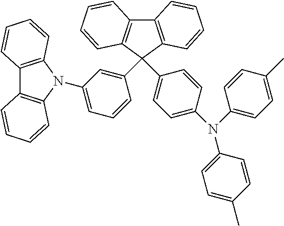 [SMILES: Cc1ccc(N(c2ccc(C)cc2)c2ccc(C3(c4cccc(-n5c6ccccc6c6ccccc65)c4)c4ccccc4-c4ccccc43)cc2)cc1] | Sp-mCzT |
| 2 | 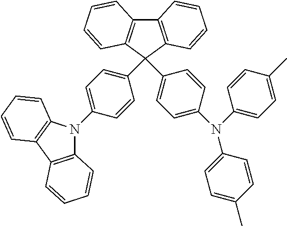 [SMILES: Cc1ccc(N(c2ccc(C)cc2)c2ccc(C3(c4ccc(-n5c6ccccc6c6ccccc65)cc4)c4ccccc4-c4ccccc43)cc2)cc1] | Sp-pCzT |

In order to clearly illustrate the method for preparing the organic compounds according to Formula (I), the preparation of the compounds disclosed in Examples 1-2 are described in detail as below.

### Example 1

### Preparation of the Compound Sp-mCzT

9H-Carbazole (1 equivalent), 1-bromo-3-iodobenzene (1.1 equivalent), and K2CO3 (1.1 equivalent) were added into a 1000 mL bottle and dissolved into dimethyl fumarate (DMF, 250 ml). Next, the mixture was heated to reflux (at about 150° C.) for 24 hrs. After cooling, 300 mL of ethyl actate (EA) was added into the bottle. After stirring, the result was filtrated to remove slats and solids. Next, 100 mL of slat water and 300 mL of water were added into the bottle, and the result was extracted by ethyl acetate as the extraction solvent. After concentration and purification by column chromatography, a compound (1) was obtained with a yield of 75%. The synthesis pathway of the reaction was as follows:

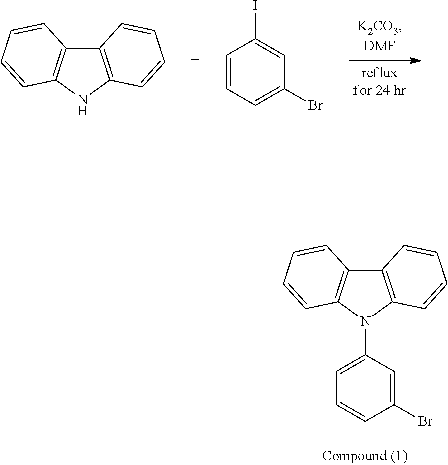 [SMILES: c1ccc2c(c1)[nH]c1ccccc12 ; Brc1cccc(I)c1 ; Brc1cccc(-n2c3ccccc3c3ccccc32)c1]

Compound (1) (1.1 equivalent) was added into a bottle and dissolved in tetrahydrofuran (THF). After cooling to −78° C., n-BuLi (1.1 equivalent) was slowly added into the bottle. After stirring for 30 min, 9-fluorenone(1 equivalent) was added into the bottle, and the mixture was stirred at −78° C. for 30 min. After reacting at room temperature for 2 hrs, the result was extracted by water, and an organic layer was collected and dried by magnesium sulfate. After purification by column chromatography and recrystallization, a compound (2) (white crystal) was obtained with a yield of 82%. The synthesis pathway of the reaction was as follows:

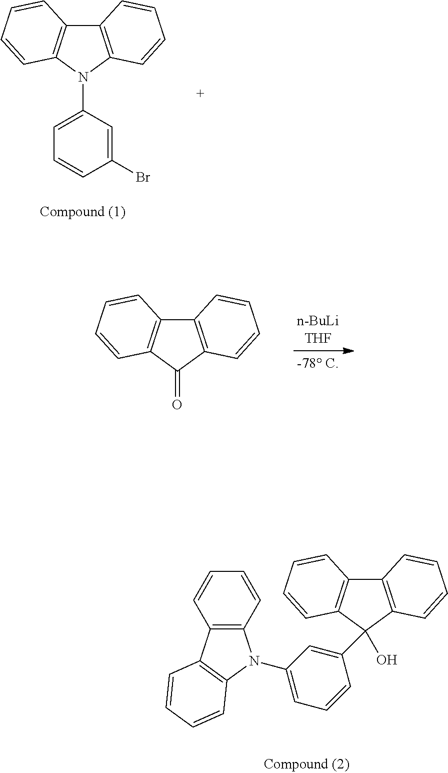 [SMILES: Brc1cccc(-n2c3ccccc3c3ccccc32)c1 ; O=C1c2ccccc2-c2ccccc21 ; OC1(c2cccc(-n3c4ccccc4c4ccccc43)c2)c2ccccc2-c2ccccc21]

Compound (2) (1 equivalent), and compound (3) (having a structure represented by

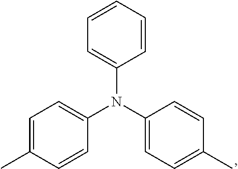

1.1 equivalent) were added into a bottle and dissolved in 1,4-dioxane (100 ml). CF₃SO₃H (as the catalyst) was slowly added into the bottle. Next, the mixture was heated to reflux for 12 hrs, and the solution gradually became a dark solution. Next, the result was extracted by water and ethyl acetate (EA). After concentration and purification by column chromatography, the result was purified by a sublimation process at the temperature of 310° C. and the pressure of 5×10⁻⁶ ton, and a compound Sp-mCzT was obtained with a yield of 70%. The synthesis pathway of the reaction was as follows:

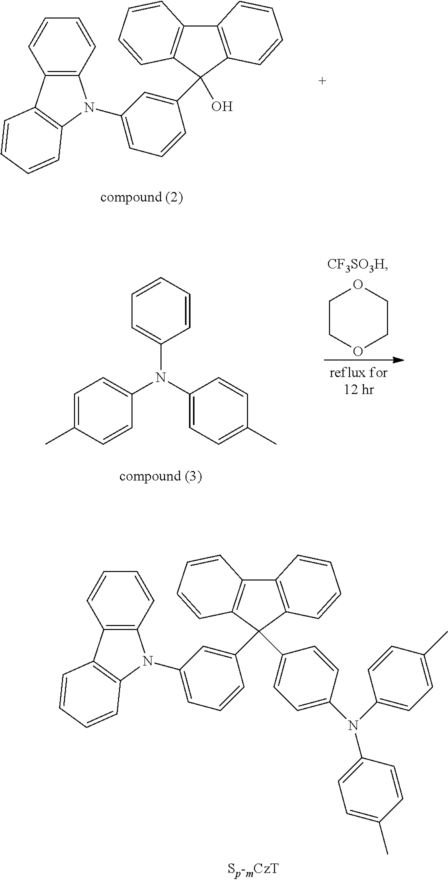

Physical measurement of the compound Sp-mCzT is listed below:

¹H NMR (200 MHz, CDCl₃): 8.13 (d, J=7.4 Hz, 2H), 7.77 (d, J=6.6 Hz, 2H), 7.58-7.30 (m, 16H), 7.17-6.85 (m, 12H), 2.29 (s, 6H).

### Example 2

### Preparation of the Compound Sp-pCzT

9H-Carbazole (1 equivalent), 1-bromo-4-iodobenzene (1.1 equivalent), and K₂CO₃ (1.1 equivalent) were added into a 1000 mL bottle and dissolved into dimethyl fumarate (DMF, 250 ml). Next, the mixture was heated to reflux (at about 150° C.) for 24 hrs. After cooling, 300 mL of ethyl actate (EA) was added into the bottle. After stirring, the result was filtrated to remove slats and solids. Next, 100 mL of slat water and 300 mL of water were added into the bottle, and the result was extracted by ethyl acetate as the extraction solvent. After concentration and purification by column chromatography, a compound (4) was obtained with a yield of 75%. The synthesis pathway of the reaction was as follows:

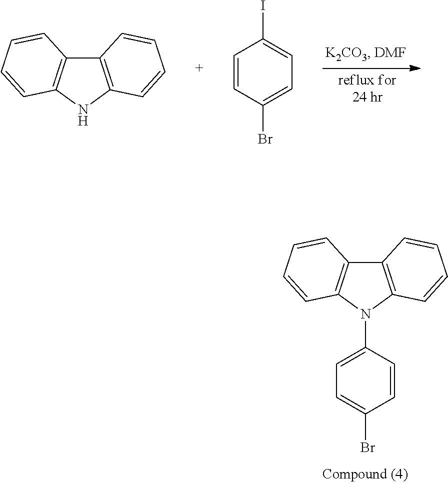 [SMILES: c1ccc2c(c1)[nH]c1ccccc12 ; Brc1ccc(I)cc1 ; Brc1ccc(-n2c3ccccc3c3ccccc32)cc1]

Compound (4) (1.1 equivalent) was added into a bottle and dissolved in tetrahydrofuran (THF). After cooling to −78° C., n-BuLi (1.1 equivalent) was slowly added into the bottle. After stirring for 30 min, 9-fluorenone (1 equivalent) was added into the bottle, and the mixture was stirred at −78° C. for 30 min. After reacting at room temperature for 2 hrs, the result was extracted by water, and an organic layer was collected and dried by magnesium sulfate. After purification by column chromatography and recrystallization, a compound (5) (white crystal) was obtained with a yield of 78%. The synthesis pathway of the reaction was as follows:

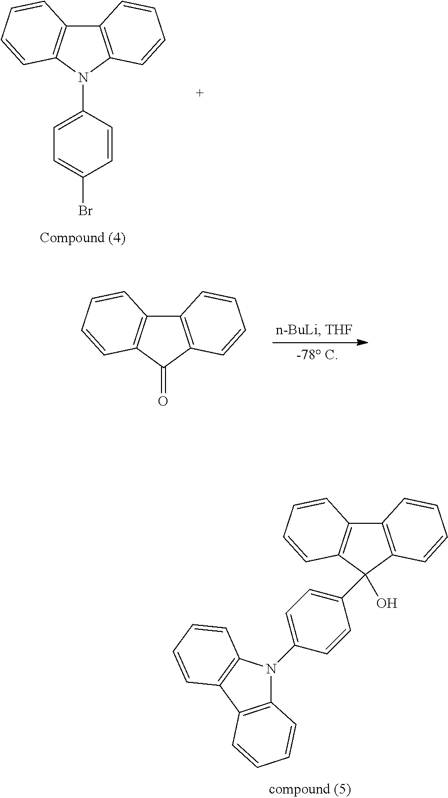 [SMILES: Brc1ccc(-n2c3ccccc3c3ccccc32)cc1 ; O=C1c2ccccc2-c2ccccc21 ; OC1(c2ccc(-n3c4ccccc4c4ccccc43)cc2)c2ccccc2-c2ccccc21]

Compound (5) (1 equivalent), and compound (3) (having a structure represented by

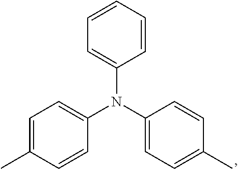

1.1 equivalent) were added into a bottle and dissolved in 1,4-dioxane (100 ml). CF₃SO₃H (as the catalyst) was slowly added into the bottle. Next, the mixture was heated to reflux for 12 hrs, and the solution gradually became a dark solution. Next, the result was extracted by water and ethyl acetate (EA). After concentration and purification by column chromatography, the result was purified by a sublimation process at the temperature of 310° C. and the pressure of 5×10⁻⁶ torr, and a compound Sp-pCzT was obtained with a yield of 72%. The synthesis pathway of the reaction was as follows:

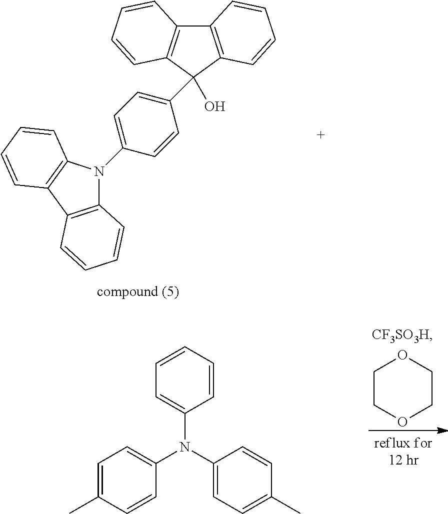

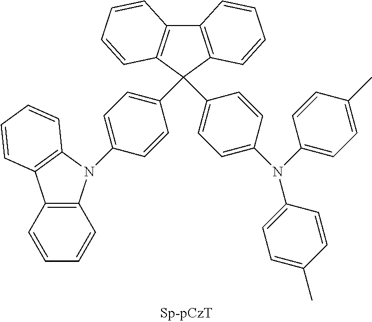 [SMILES: Cc1ccc(N(c2ccc(C)cc2)c2ccc(C3(c4ccc(-n5c6ccccc6c6ccccc65)cc4)c4ccccc4-c4ccccc43)cc2)cc1]

Physical measurement of the compound Sp-pCzT is listed below:

¹H NMR (200 MHz, CDCl₃): 8.12 (d, J=7.6 Hz, 2H), 7.81 (d, J=7.4 Hz, 2H), 7.54-7.29 (m, 16H), 7.11-6.87 (m, 12H), 2.29 (s, 6H).

Properties of the Compounds Sp-mCzT and Sp-pCzT

The molecular weight (measured via elemental analyzer), glass transition temperature (Tg), and decomposition temperature (Td) (measured via TGA (therapeutic goods administration)), of the compounds Sp-mCzT, and Sp-pCzT were measured, and the results are compared with the properties of TAPC, as shown in Table 2:

TABLE 2

| compound | Sp-pCzT | Sp-mCzT | TAPC |
|---|---|---|---|
| molecular | 678 | 678 | 627 |
| weight | | | |
| Td | 358° C. | 367° C. | ~290° C. |
| Tg | 123° C. | 118° C. | 78° C. |

As shown in Table 2, the decomposition temperature (Td) of the compounds Sp-pCzT and Sp-mCzT of the disclosure were both more than 350, and the glass transition temperature (Tg) of the compounds Sp-pCzT and Sp-mCzT of the disclosure were both more than 115° C. In comparison with the conventional hole transport material TAPC, the compounds having the Formula (I) of the disclosure exhibited higher thermal stability.

Measurement of Charge Mobility

A time-of-flight mobility measuring method was used for measuring the charge mobility of the compounds Sp-pCzT and Sp-mCzT, and the results are shown in Table 3. In Table 3, it is shown that the compounds Sp-pCzT and Sp-mCzT can have a hole transport rate of 2.05×10⁻⁴ cm²/Vs with an electric field of 755 (V/cm)^{1/2}. Since BmPyPB, which is a well used electron transport material, has an electron transport rate of 1.00×10⁻⁴ cm²/Vs, the difference between the hole and electron transport rates is small, resulting in the electrons being able to recombine with the holes in the light-emission layer.

TABLE 3

| compound | Sp-pCzT | Sp-mCzT | BmPyPB |
|---|---|---|---|
| E½ | 755 | 755 | — |
| mobility(cm²/Vs) | 2.05E−4 | 6.74E−5 | 1.00E−4 |

Measurement of Energy Gap

The energy gaps of the compounds Sp-mCzT and Sp-pCzT were measured by the photoelectron spectrometer (AC-2) and ultraviolet absorption spectrophotometry, and the results are compared with the energy gap of NPB (N,N′-di(naphthalene-1-yl)-N,N′-diphenyl-benzidine) and shown in Table 4.

In Table 4, the HOMO energy levels of the compounds Sp-mCzT and Sp-pCzT are similar to that of NPB. The energy gaps of the compounds Sp-mCzT and Sp-pCzT are 3.6 eV due to the low double-bond conjugation thereof, and the compounds Sp-mCzT and Sp-pCzT have lower LUMO energy levels (2.0 and 2.1 eV respectively) in comparison with NBP. Therefore, the organic compounds having the Formula (I) of the disclosure can serve as electron blocking layer.

TABLE 4

| compound | Sp-pCzT | Sp-mCzT | NPB |
|---|---|---|---|
| HOMO | 5.7 eV | 5.6 eV | 5.4 eV |
| LUMO | 2.1 eV | 2.0 eV | 2.4 eV |
| Eg | 3.6 eV | 3.6 eV | 3.0 eV |

Table 5 lists well used host materials of light-emission layers, such as TCTA(4,4′,4′-tri(N-carbazolyl)triphenylamine), mCP(N,N′-dicarbazolyl-3,5-dibenzene, blue phosphorescent host), CBP(4,4′-bis(9-carbazolyl)-biphenyl, red and green phosphorescent host). TCTA has a LUMO level of 2.4 eV and NBP also has a LUMO level of about 2.4 eV, and there is no obvious difference therebetween. In comparison with NBP, Sp-mCzT has a LUMO level of about 2.0 eV, and there is a LUMO level difference between TCTA and Sp-mCzT, resulting in the electron staying at light-emission layer and not being apt to further move into hole transport layer and. Therefore, the compound Sp-mCzT can block electrons from the hole transport layer.

TABLE 5

| | S1 | T1 | | |
|---|---|---|---|---|
| | (single spin state) | (triplet spin state) | HOMO | LUMO |
| TCTA | 3.4 eV | 2.9 eV | 5.83 eV | 2.43 eV |
| CBP | 3.5 eV | 2.6 eV | 6.3 eV | 2.8 eV |
| mCP | 3.5 eV | 2.9 eV | 5.9 eV | 2.4 eV |

Organic Electroluminescence Device

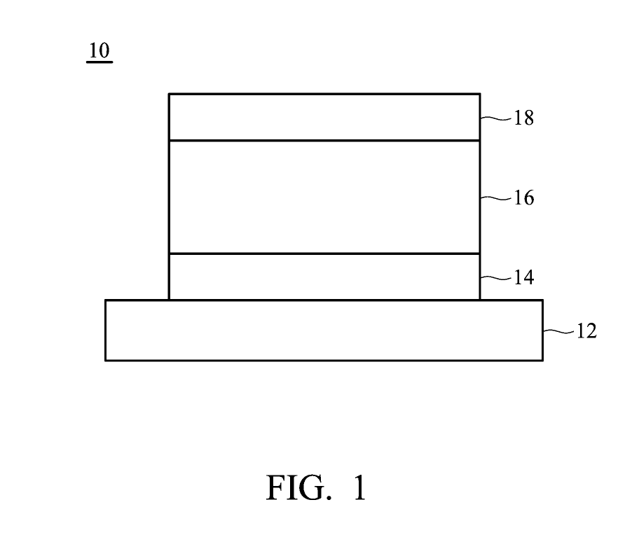

FIG. 1 shows an embodiment of an organic electroluminescent device 10. The electroluminescent device 100 includes a substrate 12, a bottom electrode 14, an electroluminescent element 16, and a top electrode 18, as shown in FIG. 1. The organic electroluminescent device can be top-emission, bottom-emission, or dual-emission devices.

The substrate 12 can be a glass plastic, or semiconductor substrate. Suitable material for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Further, al least one of the bottom and top electrodes 14 and 18 is transparent.

The electroluminescent element 16 at least includes a light-emission layer, and can further include a hole injection layer, a hole transport layer, an electron transport layer, and an electron injection layer. In an embodiment of the disclosure, at least one layer of the electroluminescent element 16 includes the organic compounds having the Formula (I). Particularly, the hole transport layer can have the organic compounds having the Formula (I).

In order to clearly disclose the organic electroluminescent devices of the disclosure, the following examples (using Sp-mCzT and Sp-pCzT as a hole transport material) and comparative examples are intended to illustrate the disclosure more fully without limiting their scope, since numerous modifications and variations will be apparent to those skilled in this art.

### Example 3

### Organic Electroluminescence Device (1)

A glass substrate with an indium tin oxide (ITO) film of 120 nm was provided and then washed with a cleaning agent, acetone, and isopropanol with ultrasonic agitation.

After drying with a nitrogen flow, the ITO film was subjected to a UV/ozone treatment. Next, TAPC (1,1-bis(di-4-tolylaminophenyl)cyclohexane, with a thickness of 40 nm), TCTA (4′,4′-tri(N-carbazolyl)triphenylamine) doped with Firpic (Iridium-bis(4,6-difluorophenyl-pyridinato-N,C2)-picolinate) (the ratio between TCTA and Firpic was 100:12, with a thickness of 10 nm), CzDBS (having a structure of

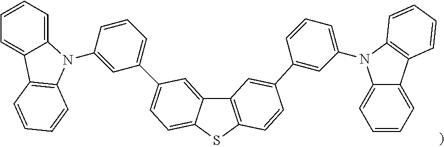 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with Firpic (the ratio between CzDBS and Firpic was 100:15, with a thickness of 10 nm), TmPyPB (1,3,5-tri[3-pyridyl phen-3-yl]benzene, with a thickness of 40 nm), Cs₂CO₃ (with a thickness of 1 nm), and Al (with a thickness of 150 nm), were subsequently formed on the ITO film at 1×10⁻⁶ torr, obtaining the organic electroluminescent device (1). The materials and layers formed therefrom are described in the following.

ITO/TAPC/TCTA:Firpic/CzDBS:Firpic/TmPyPB/Cs₂CO₃/Al

The optical property of the organic electroluminescent device (1), as described in Example 3, was measured by a PR650 (purchased from Photo Research Inc.) and a Minolta TS110. The result is shown in Table 6.

### Example 4

### Organic Electroluminescence Device (2)

A glass substrate with an indium tin oxide (ITO) film of 120 nm was provided and then washed with a cleaning agent, acetone, and isopropanol with ultrasonic agitation.

After drying with a nitrogen flow, the ITO film was subjected to a UV/ozone treatment. Next, Sp-mCzT, TCTA (4′,4′-tri(N-carbazolyl)triphenylamine) doped with Firpic (Iridium-bis(4,6-difluorophenyl-pyridinato-N,C2)-picolinate) (the ratio between TCTA and Firpic was 100:12, with a thickness of 10 nm), CzDBS (having a structure of

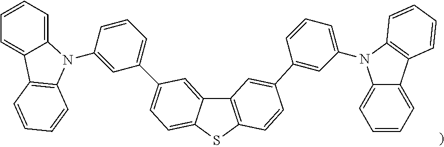 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with Firpic (the ratio between CzDBS and Firpic was 100:15, with a thickness of 10 nm), TmPyPB (1,3,5-tri[3-pyridyl phen-3-yl]benzene, with a thickness of 40 nm), Cs₂CO₃ (with a thickness of 1 nm), and Al (with a thickness of 150 nm), were subsequently formed on the ITO film at 1×10⁻⁶ torr, obtaining the organic electroluminescent device (2). The materials and layers formed therefrom are described in the following.

ITO/Sp-mCzT/TCTA:Firpic/CzDBS:Firpic/TmPyPB/Cs₂CO₃/Al

The optical property of the organic electroluminescent device (2), as described in Example 4, was measured by a PR650 (purchased from Photo Research Inc.) and a Minolta TS110. The result is shown in Table 6.

TABLE 6

| | | |
|---|---|---|
| | Current efficiency | |
| Voltage (V) | (cd/A) | CIE (X, Y) |

measured at a brightness of 1000 Cd/m²

| | | | |
|---|---|---|---|
| electroluminescent | 3.6 | 33.9 | (0.16, 0.38) |
| device (1) | | | |
| electroluminescent | 5 | 36.6 | (0.17, 0.36) |
| device (2) | | | |

As shown in Table 6, with the premise that the same light-emission layer was used, the blue light organic electroluminescent device (2) employing Sp-mCzT as a hole transport layer showed superior efficiency (promotion of 2.1 Cd/A (8%) at 5V) in comparison with the organic electroluminescent device (1) employing the TAPC as a hole transport layer.

### Example 5

### Organic Electroluminescence Device (3)

A glass substrate with an indium tin oxide (ITO) film of 120 nm was provided and then washed with a cleaning agent, acetone, and isopropanol with ultrasonic agitation.

After drying with a nitrogen flow, the ITO film was subjected to a UV/ozone treatment. Next, TAPC (1,1-bis(di-4-tolylaminophenyl)cyclohexane, with a thickness of 40 nm), TCTA (4′,4′-tri(N-carbazolyl)triphenylamine) doped with Firpic (Iridium-bis(4,6-difluorophenyl-pyridinato-N,C2)-picolinate) (the ratio between TCTA and Firpic was 100:12, with a thickness of 10 nm), PO-01 (having a structure of

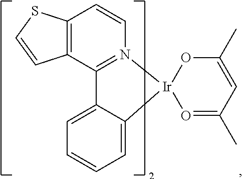

with a thickness of 1 nm), CzDBS (having a structure of

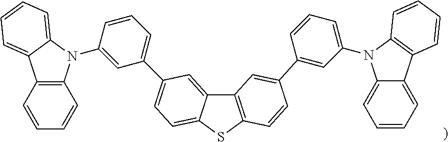 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with Firpic (the ratio between CzDBS and Firpic was 100:15, with a thickness of 10 nm), TmPyPB (1,3,5-tri[3-pyridyl phen-3-yl]benzene, with a thickness of 40 nm), Cs₂CO₃ (with a thickness of 1 nm), and Al (with a thickness of 150 nm), were subsequently formed on the ITO film at 1×10⁻⁶ torr, obtaining the organic electroluminescent device (3). The materials and layers formed therefrom are described in the following.

ITO/TAPC/TCTA:Firpic/PO-01/CzDBS:Firpic/TmPyPB/Cs₂CO₃/Al

The optical property of the organic electroluminescent device (3), as described in Example 5, was measured by a PR650 (purchased from Photo Research Inc.) and a Minolta TS110. The result is shown in Table 7.

### Example 6

### Organic Electroluminescence Device (4)

A glass substrate with an indium tin oxide (ITO) film of 120 nm was provided and then washed with a cleaning agent, acetone, and isopropanol with ultrasonic agitation.

After drying with a nitrogen flow, the ITO film was subjected to a UV/ozone treatment. Next, Sp-mCzT (with a thickness of 40 nm), TCTA (4′,4′-tri(N-carbazolyl)triphenylamine) doped with Firpic (Iridium-bis(4,6-difluorophenyl-pyridinato-N,C2)-picolinate) (the ratio between TCTA and Firpic was 100:12, with a thickness of 10 nm), PO-01 (having a structure of

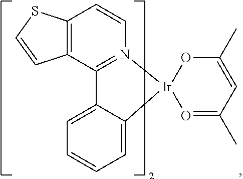

with a thickness of 1 nm), CzDBS (having a structure of

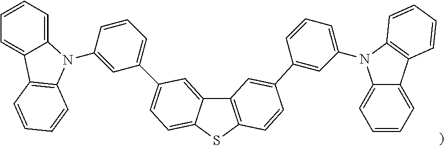 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with Firpic (the ratio between CzDBS and Firpic was 100:15, with a thickness of 10 nm), TmPyPB (1,3,5-tri[3-pyridyl phen-3-yl]benzene, with a thickness of 40 nm), Cs₂CO₃ (with a thickness of 1 nm), and Al (with a thickness of 150 nm), were subsequently formed on the ITO film at 1×10⁻⁶ torr, obtaining the organic electroluminescent device (4). The materials and layers formed therefrom are described in the following.

ITO/Sp-mCzT/TCTA:Firpic/PO-01/CzDBS:Firpic/TmPyPB/Cs₂CO₃/Al

The optical property of the organic electroluminescent device (4), as described in Example 6, was measured by a PR650 (purchased from Photo Research Inc.) and a Minolta TS110. The result is shown in Table 7.

TABLE 7

| | | |
|---|---|---|
| | Current efficiency | |
| Voltage (V) | (cd/A) | CIE (X, Y) |

measured at a brightness of 1000 Cd/m²

| | | | |
|---|---|---|---|
| electroluminescent | 3.4 | 48 | (0.45, 0.49) |
| device (3) | | | |
| electroluminescent | 4.4 | 48.22 | (0.45, 0.49) |
| device (4) | | | |

Since a yellow phosphorescent light-emission layer was disposed between two blue light-emission layers, the organic electroluminescent devices (3) and (4) achieved white light emission. As shown in Table 7, with the premise that the same light-emission layer was used, the organic electroluminescent device (4) employing Sp-mCzT as a hole transport layer showed similar efficiency in comparison with the organic electroluminescent device (3) employing the TAPC as a hole transport layer.

Accordingly, in both blue light and white light organic electroluminescent devices, the organic electroluminescent devices employing the compounds having the Formula (I) of the disclosure as a hole transport material exhibited superior efficiency in comparison with the organic electroluminescent devices employing the conventional hole transport material TAPC. Further, the compounds having the Formula (I) of the disclosure exhibited high thermal stability and are suitable for application in an organic electroluminescent device.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic compound having a Formula (I), of: 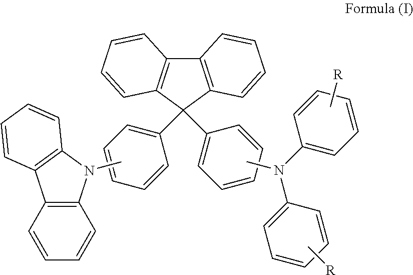
wherein, R are independent and hydrogen, halogen, cyano, C₁₋₈ alkyl, C₁₋₈ alkoxy, C₅₋₁₀ aryl, or C₂₋₈ heteroaryl.

2. The organic compound as claimed in claim 1, wherein the organic compound has a Formula (II) or Formula (III), of: 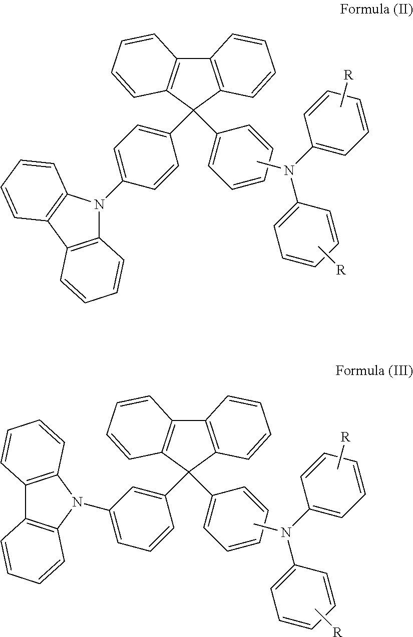
wherein, R are independent and hydrogen, halogen, cyano, C₁₋₈ alkyl, C₁₋₈ alkoxy, C₅₋₁₀ aryl, or C₂₋₈ heteroaryl.

3. The organic compound as claimed in claim 1, wherein R are independent and a methyl group, ethyl group, propyl group, isopropyl group, butyl group, tert-butyl group, pentyl group, or hexyl group.

4. The organic compound as claimed in claim 1, wherein R are independent and a methoxy group, ethoxy group, propoxy group, isopropoxy group, butoxy group, isobutoxy group, pentyloxy group, or hexyloxy group.

5. The organic compound as claimed in claim 1, wherein R are independent and phenyl, biphenyl, pyridyl, furyl, carbazole, naphthyl, anthryl, phenanthrenyl, imidazolyl, pyrimidinyl, quinolinyl, indolyl, or thiazolyl.

6. The organic compound as claimed in claim 1, wherein the organic compound comprises

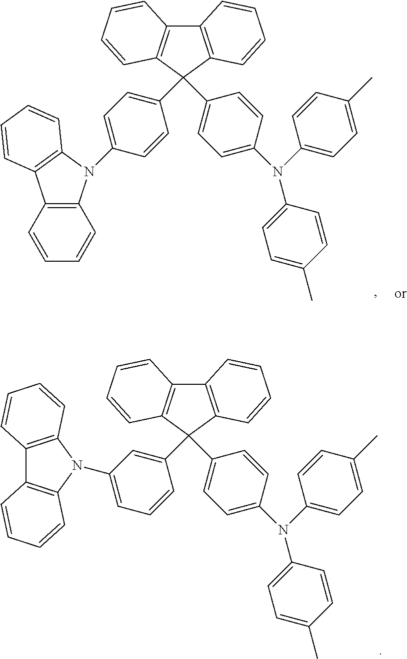 [SMILES: Cc1ccc(N(c2ccc(C)cc2)c2ccc(C3(c4ccc(-n5c6ccccc6c6ccccc65)cc4)c4ccccc4-c4ccccc43)cc2)cc1 ; Cc1ccc(N(c2ccc(C)cc2)c2ccc(C3(c4cccc(-n5c6ccccc6c6ccccc65)c4)c4ccccc4-c4ccccc43)cc2)cc1]

7. An organic electroluminescence device, comprising:
a pair of electrodes; and
an electroluminescent element, disposed between the pair of electrodes, wherein the electroluminescent element comprises the organic compound as claimed in claim 1.

8. An organic electroluminescence device, comprising:
a pair of electrodes; and
an electroluminescent element, disposed between the pair of electrodes, wherein the electroluminescent element comprises an emission layer comprising a hole transport layer, and the hole transport layer comprises the organic compound as claimed in claim 1.
